(19) United States
(12) Patent Application Publication
(10) Pub. No.: US 2012/0212871 A1
(43) Pub. Date: Aug. 23, 2012

(54) OVERCURRENT DETECTING CIRCUIT AND BATTERY PACK

(76) Inventor: Keitaro Taniguchi, Hyogo (JP)

(21) Appl. No.: 13/502,995

(22) PCT Filed: May 18, 2011
(86) PCT No.: PCT/JP2011/002754

§ 371 Date: Apr. 19, 2012

(30) Foreign Application Priority Data
May 25, 2010 (JP) 2010-119129

(51) Int. Cl. H02H 3/08; G01R 31/36

(52) U.S. Cl. 361/87; 324/426

(57) ABSTRACT

An overcurrent detecting circuit includes: a voltage detecting unit that detects a terminal voltage of a battery; a variation detecting unit that detects a variation in the terminal voltage within a base time set in advance, based on a terminal voltage detected by the voltage detecting unit; and an overcurrent judging unit that judges that an overcurrent has flowed inside the battery in a case where a variation detected by the variation detecting unit exceeds a reference threshold value set in advance.

### RELATED APPLICATIONS

This application is the U.S. National Phase under 35 U.S.C. §371 of International Application No. PCT/JP2011/002754, filed on May 18, 2011, which in turn claims the benefit of Japanese Application No. 2010-119129, filed on May 25, 2010, the disclosures of which Applications are incorporated by reference herein.

### TECHNICAL FIELD

The present invention relates to an overcurrent detecting circuit which detects an overcurrent that flows inside a battery, and a battery pack provided with the overcurrent detecting circuit.

### BACKGROUND ART

When a short circuit of a battery occurs, an overcurrent flows inside the battery. An overcurrent flowing through a battery may cause battery degradation. In consideration thereof, overcurrent protection circuits are known which are designed to detect an overcurrent and protect a battery by interrupting a current when a current flowing inside the battery exceeds a predetermined judgment value (for example, refer to Patent Document 1 and Patent Document 2).

In an overcurrent protection circuit described in Patent Document 1, a shunt resistor and a switching element for battery protection is connected in series with a battery. The overcurrent protection circuit is capable of detecting an overcurrent by detecting a current that flows inside the battery from a voltage between both ends of the shunt resistor.

In addition, in an overcurrent protection circuit described in Patent Document 2, an FET (Field Effect Transistor) for battery protection is connected in series with a battery. The overcurrent protection circuit is capable of detecting an overcurrent by detecting a current that flows inside the battery from a voltage between both ends of the FET based on the fact that an on-resistance is created when the FET is turned on.

However, the overcurrent protection circuit described in Patent Document 1 requires a shunt resistor in order to detect an overcurrent and, as a result, the number of parts increases. In addition, a power loss disadvantageously occurs at the shunt resistor when a current flows inside the shunt resistor.

Furthermore, with the overcurrent protection circuit described in Patent Document 2, since a voltage appropriate for a flowing current must be generated between both ends of the FET, an FET with a relatively high on-resistance must be deliberately used. Therefore, compared to a case where the on-resistance of an FET is not used to detect an overcurrent, there is a disadvantage that the on-resistance of the FET increases and, accordingly, a power loss at the FET also increases.

Patent Document 1: Japanese Patent Application Laid-open No. H6-225451

Patent Document 2: Japanese Patent Application Laid-open No. 2001-14042

### SUMMARY OF THE INVENTION

An object of the present invention is to provide an overcurrent detecting circuit capable of detecting an overcurrent of a battery without using a shunt resistor or an on-resistance of an FET, and a battery pack provided with the overcurrent detecting circuit.

An overcurrent detecting circuit according to an aspect of the present invention includes: a voltage detecting unit that detects a terminal voltage of a battery; a variation detecting unit that detects a variation in the terminal voltage within a base time set in advance, based on a terminal voltage detected by the voltage detecting unit; and an overcurrent judging unit that judges that an overcurrent has flowed inside the battery in a case where a variation detected by the variation detecting unit exceeds a reference threshold value set in advance.

In addition, a battery pack according to an aspect of the present invention includes the overcurrent detecting circuit and the battery described above.

### BRIEF DESCRIPTION OF THE DRAWINGS

FIG. 1 is a block diagram showing an example of a configuration of a battery pack using an overcurrent detecting circuit according to a first embodiment of the present invention.

FIG. 2 is a block diagram showing an example of a configuration of a battery pack according to a second embodiment of the present invention.

FIG. 3 is a flow chart showing an example of operations of an overcurrent protection circuit shown in FIG. 2.

FIG. 4 is a block diagram showing a modification of the battery pack shown in FIG. 1.

### DESCRIPTION OF EMBODIMENTS

Hereinafter, embodiments of the present invention will be described with reference to the drawings. In the drawings, components denoted by like reference characters represent like components and a description thereof will be omitted.

### First Embodiment

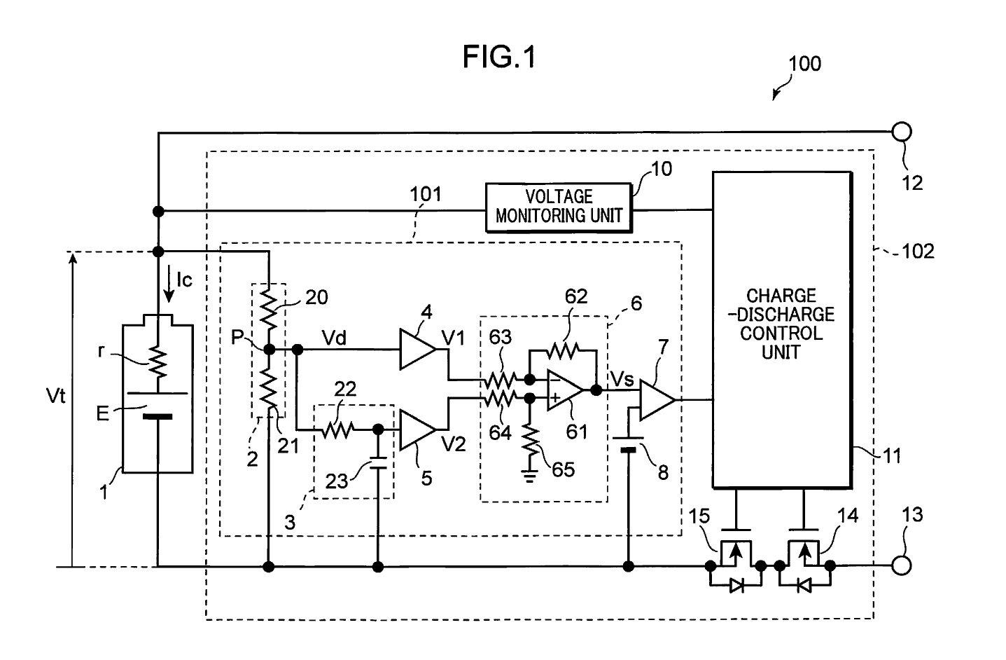

FIG. 1 is a block diagram showing an example of a configuration of a battery pack using an overcurrent detecting circuit according to a first embodiment of the present invention. A battery pack 100 shown in FIG. 1 has a battery 1, an overcurrent protection circuit 102, and connecting terminals 12 and 13. The overcurrent protection circuit 102 includes an overcurrent detecting circuit 101, a voltage monitoring unit 10, a charge-discharge control unit 11, a charge control FET (Field Effect Transistor) 14, and a discharge control FET 15.

For example, the battery 1 is a secondary battery such as a lithium-ion secondary battery or a nickel hydride secondary battery. The battery 1 is not limited to a single cell and may instead be an assembled battery which combines a plurality of cells. In addition, the battery 1 may alternatively be a primary battery.

For example, as shown in FIG. 1, the battery 1 may conceptually be expressed as a series circuit constituting a voltage source with an electromotive force E and an internal resistor with a resistance value r. Therefore, if a charging direction of a current Ic flowing inside the battery 1 is denoted by a positive polarity and a discharging direction by a negative polarity, then a terminal voltage Vt of the battery 1 may be expressed by the following expression (1).

Vt=E+r×Ic (1)

As shown by expression (1), the terminal voltage Vt of the battery 1 increases when the current Ic flows in the charging direction (positive) and decreases when the current Ic flows in the discharging direction (negative). In addition, the greater a variation in the current Ic, the greater a variation in the terminal voltage Vt.

A positive electrode of the battery 1 is connected to the connecting terminal 12. A negative electrode of the battery 1 is connected to the connecting terminal 13 via the discharge control FET 15 and the charge control FET 14.

The charge control FET 14 and the discharge control FET 15 respectively include parasitic diodes. In addition, the parasitic diode of the charge control FET 14 is arranged so that a direction in which a discharge current of the battery 1 flows (a direction from the connecting terminal 13 to the negative electrode of the battery 1) coincides with a forward direction of the parasitic diode. Accordingly, the charge control FET 14 is configured so that when turned off, only a current in the charging direction of the battery 1 (a direction from the negative electrode of the battery 1 toward the connecting terminal 13) is interrupted. The parasitic diode of the charge control FET 14 corresponds to an example of a first diode.

Furthermore, the parasitic diode of the discharge control FET 15 is arranged so that a direction in which a charge current of the battery 1 flows coincides with a forward direction of the parasitic diode. Accordingly, the discharge control FET 15 is configured so that when turned off, only a current in the discharging direction of the battery 1 is interrupted. The parasitic diode of the discharge control FET 15 corresponds to an example of a second diode.

The voltage monitoring unit 10 has a comparator and the like, for example. The voltage monitoring unit 10 compares a terminal voltage Vt of the battery 1 with, for example, a judgment voltage Vov set in advance for judging an overvoltage, and when the terminal voltage Vt exceeds the judgment voltage Vov, outputs an overvoltage signal indicating that an overvoltage has been created to the charge-discharge control unit 11.

The overcurrent detecting circuit 101 includes a voltage-dividing resistor 2, a low-pass filter 3, buffers 4 and 5, a differential amplifier circuit 6, a comparator 7, and a reference voltage source 8. In addition, the voltage-dividing resistor 2 is configured with resistors 20 and 21 connected in series. The voltage-dividing resistor 2 is connected in parallel to the battery 1 and is arranged to divide a terminal voltage Vt using the resistors 20 and 21.

In this case, the voltage-dividing resistor 2 and the buffer 4 correspond to examples of a voltage detecting unit, the low-pass filter 3 corresponds to a first-order lag circuit that is an example of a delaying unit, the differential amplifier circuit 6 corresponds to an example of a difference unit, the comparator 7 corresponds to an example of an overcurrent judging unit, the charge control FET 14 corresponds to an example of a charging switching element, and the discharge control FET 15 corresponds to an example of a discharging switching element.

Moreover, while an example has been shown in which a switching unit is configured with the charge control FET 14 and the discharge control FET 15 connected in series, a single switching element that interrupts currents bi-directionally may alternatively be used as the switching unit. In this case, instead of turning off the charge control FET 14 or the discharge control FET 15, the single switching element may be turned off

For example, the buffers 4 and 5 are a non-inverting operational amplifier having an amplification factor of 1. An input terminal of the buffer 4 is connected to a connection point P of the resistors 20 and 21. In addition, the buffer 4 outputs a divided voltage Vd obtained by being divided by the resistors 20 and 21 to the differential amplifier circuit 6 as a voltage V1. Since the divided voltage Vd is proportional to the terminal voltage Vt, the divided voltage Vd is used as a signal that represents the terminal voltage Vt.

The low-pass filter 3 is configured as a first-order lag circuit using a resistor 22 and a capacitor 23. The capacitor 23 is connected between an input terminal of the buffer 5 and the negative electrode of the battery 1. The resistor 22 is connected between the input terminal of the buffer 5 and the connection point P. Accordingly, a change in the divided voltage Vd or, in other words, a change in the terminal voltage Vt is delayed by the low-pass filter 3 and outputted as a delayed voltage V2 by the buffer 5 to the differential amplifier circuit 6.

A resistance value of the resistor 22 and a capacitance of the capacitor 23 are set so that a delay time of the delayed voltage V2 by the low-pass filter 3 is consistent with a base time set in advance.

Consequently, the delayed voltage V2 represents a terminal voltage Vt that precedes the voltage V1 by the delay time (base time). Therefore, when the terminal voltage Vt drops, the delayed voltage V2 becomes higher than the voltage V1, and when the terminal voltage Vt rises, the delayed voltage V2 becomes lower than the voltage V1.

For example, the differential amplifier circuit 6 includes an operational amplifier 61 and resistors 62, 63, 64, and 65. The resistor 62 is connected between an output terminal and an inverting input terminal of the operational amplifier 61. A non-inverting input terminal of the operational amplifier 61 is connected to a circuit ground via the resistor 65. In addition, the inverting input terminal of the operational amplifier 61 is connected to the output terminal of the buffer 4 via the resistor 63, and the non-inverting input terminal of the operational amplifier 61 is connected to the output terminal of the buffer 5 via the resistor 64.

The differential amplifier circuit 6 amplifies a difference between the delayed voltage V2 and the voltage V1 or, in other words, V2−V1, and outputs the same as a difference voltage Vs to the comparator 7. Moreover, if the amplification factor of the differential amplifier circuit 6 is high, there is a risk that noises inside the circuit may inadvertently become amplified. Therefore, the amplification factor of the differential amplifier circuit 6 is desirably set to an amplification factor at which amplification of noise does not pose a problem such as around a factor of 1.

In this case, the voltage V1 represents the terminal voltage Vt of the battery 1 and the delayed voltage V2 represents a voltage that reflects a delay created on the voltage V1. Therefore, it is shown that the greater the difference voltage Vs, the greater the variation (amount of decrease) of the terminal voltage Vt per unit time or, in other words, the more abrupt the terminal voltage Vt varies (decreases).

The reference voltage source 8 is a constant voltage circuit that outputs a reference voltage Vref corresponding to an example of a reference threshold to the comparator 7.

The comparator 7 compares the reference voltage Vref outputted from the reference voltage source 8 with the difference voltage Vs and outputs a signal indicating a comparison result to the charge-discharge control unit 11. In this case, for example, if a short circuit occurs between the connecting terminals 12 and 13 or a short-circuit fault occurs inside the battery pack 100 to cause a short circuit between the positive and negative electrodes of the battery 1, an overcurrent flows through the battery 1. As shown, when the battery 1 is short-circuited and an overcurrent flows, a discharge current of the battery 1 increases abruptly. In other words, the current Ic takes a negative polarity and an absolute value thereof increases abruptly.

Consequently, as indicated by the expression (1) above, the terminal voltage Vt decreases abruptly. In addition, when the terminal voltage Vt decreases abruptly, the difference voltage Vs increases. In other words, the difference voltage Vs represents a variation of the terminal voltage Vt in a decreasing direction thereof.

For the reference voltage Vref, a voltage is appropriately set which is smaller than a difference voltage Vs that is created when the terminal voltage Vt decreases abruptly due to such a short circuit of the battery 1 and which is greater than a difference voltage Vs that is created by a normal load current fluctuation in a load circuit connected to the battery pack 100.

Alternatively, for example, if Ix denotes a current value desirably detected as an overcurrent, a voltage value representing a product of an internal resistance value r of the battery 1 and the current value Ix may be set as the reference voltage Vref.

Furthermore, the greater the delay time (base time) at the low-pass filter 3 or, in other words, the greater a time constant of the low-pass filter 3, the greater the difference voltage Vs obtained in accordance with a change in the terminal voltage Vt. Therefore, the time constant of the low-pass filter 3 may be set to a small value to prevent an overcurrent-related abnormality such as a short circuit from being detected if the variation of the terminal voltage Vt per unit time is not large. On the other hand, the time constant may be set to a large value in order to detect an overcurrent-related abnormality in which the variation of the terminal voltage Vt per unit time is small and in which the current value changes gradually. In this manner, the delay time of the low-pass filter 3 or, in other words, the time constant of the low-pass filter 3, and the reference voltage Vref may be appropriately set according to the variation of the terminal voltage Vt per unit time which is to be detected as an overcurrent-related abnormality.

Accordingly, as a result of a comparison performed by the comparator 7, when it is judged that the difference voltage Vs has exceeded the reference voltage Vref, an overcurrent due to a short circuit can be judged to have flowed inside the battery 1.

The charge-discharge control unit 11 includes a logic circuit and the like, for example. In addition, for example, the charge-discharge control unit 11 is arranged to turn off the charge control FET 14 to prevent an overvoltage from being applied to the battery 1 and to prevent an overcharge from being created when an overvoltage signal indicating that an overvoltage has been created is outputted from the voltage monitoring unit 10.

Furthermore, for example, the charge-discharge control unit 11 turns off the discharge control FET 15 when a signal indicating that the difference voltage Vs has exceeded the reference voltage Vref is outputted from the comparator 7 since it is conceivable that an overcurrent due to a short circuit has flowed. As described above, by shutting down a discharge current flowing inside the battery 1 by turning off the discharge control FET 15, degradation of the battery 1 due to an overcurrent can be prevented.

Moreover, a configuration may be adopted in which a voltage indicating an absolute value of the difference voltage Vs is inputted to the comparator 7. In this case, by having the charge-discharge control unit 11 interrupt the charge control FET 14 together with the discharge control FET 15 when a signal indicating that the difference voltage Vs has exceeded the reference voltage Vref is outputted from the comparator 7, for example, the battery 1 can be protected from an overcurrent even when a charge current increases abruptly due to a failure of a charger or the like.

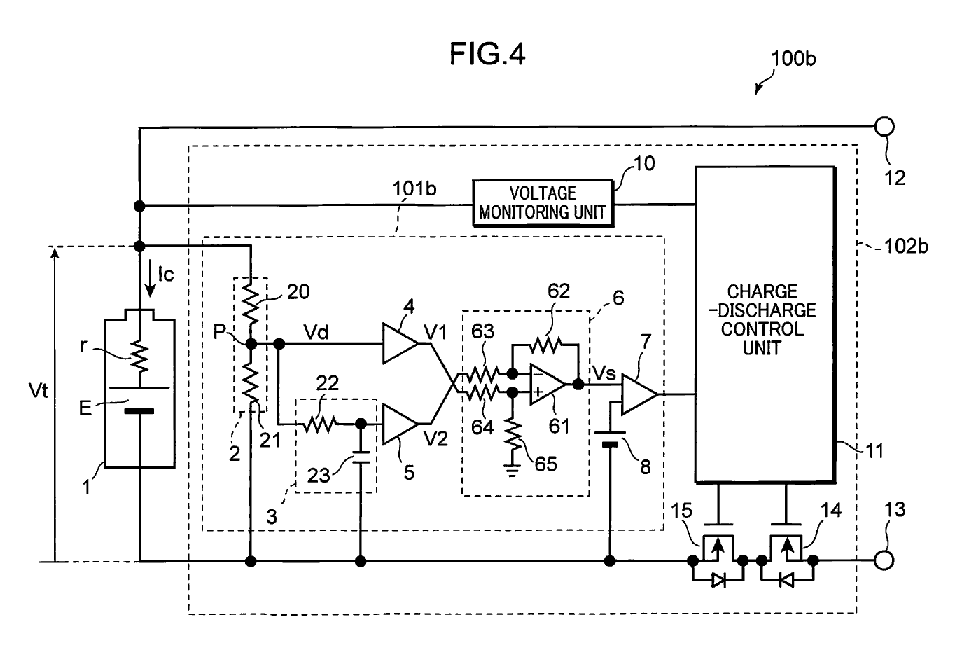

In addition, as is the case of the overcurrent detecting circuit 101b shown in FIG. 4, a configuration may be adopted in which the voltage V1 is inputted to a non-inverting input terminal of the operational amplifier 61 via the resistor 64 and the delayed voltage V2 is inputted to an inverting input terminal of the operational amplifier 61 via the resistor 63. In this case, the difference voltage Vs takes a voltage of V1−V2 amplified by an amplification factor of the differential amplifier circuit 6. Therefore, at the overcurrent detecting circuit 101b, the difference voltage Vs represents a variation of the terminal voltage Vt in an increasing direction thereof

Furthermore, in the overcurrent protection circuit 102b, since it is conceivable that a charge current has increased abruptly due to a failure of a charger or the like when a signal indicating that the difference voltage Vs has exceeded the reference voltage Vref is outputted from the comparator 7, the charge-discharge control unit 11 turns off the charge control FET 14. As described above, by interrupting a charge current flowing inside the battery 1 by turning off the charge control FET 14, degradation of the battery 1 due to an overcurrent can be prevented.

In addition, a configuration may be adopted in which by not using the charge-discharge control unit 11 and by directly connecting an output signal of the comparator 7 to a gate of the discharge control FET 15 or the charge control FET 14, the discharge control FET 15 or the charge control FET 14 is turned off when a signal indicating that the difference voltage Vs has exceeded the reference voltage Vref is outputted from the comparator 7.

As described above, according to the battery pack 100 shown in FIG. 1 and the battery pack 100b shown in FIG. 4, an overcurrent of the battery 1 caused by a short circuit can be detected and the overcurrent can be interrupted to protect the battery 1 without using a shunt resistor or an on-resistance of an FET. In this case, heat generation or unnecessary loss due to a shunt resistor does not occur. In addition, an FET with a minimal on-resistance can be used as the charge control FET 14 and the discharge control FET 15. Therefore, heat generation and power loss at the charge control FET 14 and the discharge control FET 15 can be readily reduced and an output current value of the battery 1 can be readily increased.

Furthermore, in a case of detecting an overcurrent using a shunt resistor or an on-resistance of an FET as described in Background Art, when a short-circuit fault occurs at a wiring closer to the battery than the shunt resistor or the FET, a short circuit current does not flow through the shunt resistor or the FET. Therefore, even if an overcurrent flows, the overcurrent cannot be detected.

However, since the overcurrent detecting circuit 101 shown in FIG. 1 detects an overcurrent due to a short circuit based on the terminal voltage Vt of the battery 1, a certainty of detection of an overcurrent due to a short-circuit fault occurring inside the battery pack 100 increases.

The overcurrent detecting circuits 101 and 101b and the overcurrent protection circuits 102 and 102b shown in FIGS. 1 and 4 may be mounted on a safety circuit board of a battery pack. In addition, all of or a part of the overcurrent detecting circuits 101 and 101b and the overcurrent protection circuits 102 and 102b may be configured as an integrated circuit.

Moreover, the charge-discharge control unit 11 is not necessarily limited to a unit that turns off the discharge control FET 15 when a signal indicating that the difference voltage Vs has exceeded the reference voltage Vref is outputted from the comparator 7. In addition, the charge control FET 14 and the discharge control FET 15 need not be provided.

For example, the charge-discharge control unit 11 may cause lighting of an LED indicating that an overcurrent due to a short circuit has been created or may cause a notification of a communication signal indicating that an overcurrent due to a short circuit has been created to the outside of the battery pack 100 when a signal indicating that the difference voltage Vs has exceeded the reference voltage Vref is outputted from the comparator 7.

### Second Embodiment

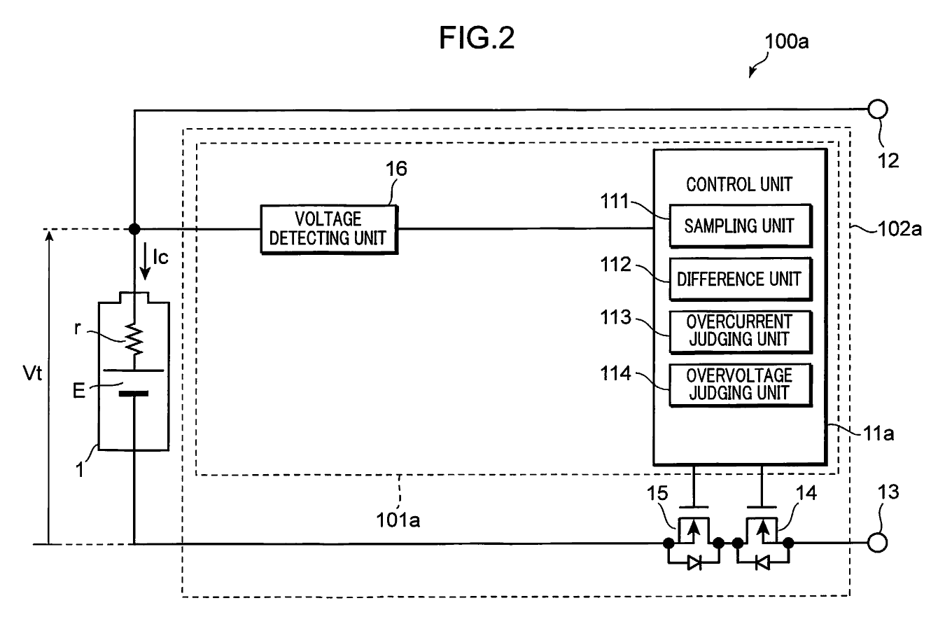

Next, a battery pack 100a having an overcurrent detecting circuit 101a according to a second embodiment of the present invention will be described. FIG. 2 is a block diagram showing an example of a configuration of the battery pack 100a according to the second embodiment of the present invention. The battery pack 100a shown in FIG. 2 and the battery pack 100 shown in FIG. 1 differ from each other on the following points.

That is, the battery pack 100a shown in FIG. 2 has an overcurrent protection circuit 102a instead of the overcurrent protection circuit 102. The overcurrent protection circuit 102a includes an overcurrent detecting circuit 101a, a charge control FET 14, and a discharge control FET 15. The overcurrent detecting circuit 101a includes a control unit 11a and a voltage detecting unit 16. Since other components are similar to those of the battery pack 100 shown in FIG. 1, a description thereof will be omitted. Hereinafter, characteristic points of the present embodiment will be described.

The voltage detecting unit 16 includes an analog-to-digital converter or the like. The voltage detecting unit 16 detects a terminal voltage Vt of the battery 1 and outputs data indicating the terminal voltage Vt to the control unit 11a.

The control unit 11a includes a CPU (Central Processing Unit) that performs predetermined logic operations, a ROM (Read Only Memory) that stores a predetermined control program, a RAM (Random Access Memory) that temporarily stores data, a timer circuit, and peripheral circuitry thereof. In addition, for example, by executing the control program stored in the ROM, the control unit 11a functions as a sampling unit 111, a difference unit 112, an overcurrent judging unit 113, and an overvoltage judging unit 114.

The overvoltage judging unit 114 compares a terminal voltage Vt detected by the voltage detecting unit 16 with a judgment voltage Vov, and when the terminal voltage Vt exceeds the judgment voltage Vov, judges that an overvoltage has been created and turns off the charge control FET 14. Accordingly, the overvoltage judging unit 114 is arranged to prevent an overvoltage from being applied to the battery 1 and to prevent an overcharge from being created in the battery 1.

The sampling unit 111 periodically samples the terminal voltage Vt detected by the voltage detecting unit 16 at a time interval ts set in advance.

The difference unit 112 calculates a difference between a terminal voltage Vt previously sampled and a terminal voltage Vt presently sampled by the sampling unit 111 as a variation Vv. Specifically, if a terminal voltage Vtp denotes a previously sampled terminal voltage Vt and a terminal voltage Vtn denotes a presently sampled terminal voltage Vt, then the difference unit 112 calculates a variation Vv based on the following expression (2). Since the terminal voltage Vtn is a terminal voltage sampled after a lapse of the time interval ts from the sampling of the terminal voltage Vtp, the terminal voltage Vtp corresponds to a first voltage and the terminal voltage Vtn corresponds to a second voltage.

Vv=Vtp−Vtn (2)

When the variation Vv calculated by the difference unit 112 exceeds a reference voltage Vref, the overcurrent judging unit 113 judges that an overcurrent has flowed inside the battery 1 due to a short-circuit fault and turns off the discharge control FET 15. Accordingly, as a result of interrupting a current flowing inside the battery 1, degradation of the battery 1 due to an overcurrent can be prevented.

Moreover, the overcurrent judging unit 113 may be arranged so that when the variation Vv calculated by the difference unit 112 takes a negative value and an absolute value of the variation Vv exceeds the reference voltage Vref, the overcurrent judging unit 113 judges that an overcurrent has flowed inside the battery 1 due to a failure of a charger or the like and turns off the charge control FET 14. Accordingly, as a result of interrupting a charge current flowing inside the battery 1, degradation of the battery 1 due to an overcurrent can be prevented.

In addition, the difference unit 112 may be arranged to calculate an absolute value of a difference between a terminal voltage Vtp previously sampled and a terminal voltage Vtn presently sampled by the sampling unit 111 as a variation Vv based on the following expression (3).

Vv=|Vtp−Vtn| (3)

In this case, when the variation Vv calculated by the difference unit 112 exceeds the reference voltage Vref, the overcurrent judging unit 113 judges that an overcurrent has flowed inside the battery 1 due to a short-circuit fault, a failure of a charger, or the like, and turns off the charge control FET 14 and the discharge control FET 15. Accordingly, as a result of interrupting a current flowing inside the battery 1, degradation of the battery 1 due to an overcurrent can be prevented.

Here, the longer the time interval ts, the greater the variation Vv obtained relative to a gradual change in the terminal voltage Vt. In addition, the greater the reference voltage Vref, the greater the value of the variation Vv at which an overcurrent is judged to have flowed.

Therefore, in order to detect an overcurrent-related abnormality when the variation of the terminal voltage Vt per unit time has a greater value, the time interval ts may be set to a short period of time or the reference voltage Vref may be set to a high voltage. In addition, in order to detect an overcurrent-related abnormality when the variation of the terminal voltage Vt per unit time is small and the current value changes gradually, the time interval ts may be set to a long period of time or the reference voltage Vref may be set to a low voltage.

In this manner, the time interval ts and the reference voltage Vref may be appropriately set according to the variation of the terminal voltage Vt per unit time which is to be detected as an overcurrent-related abnormality. For example, a period of time from around 10 msec to 100 msec can be favorably used as the time interval ts. In particular, the time interval ts is desirably around 10 msec.

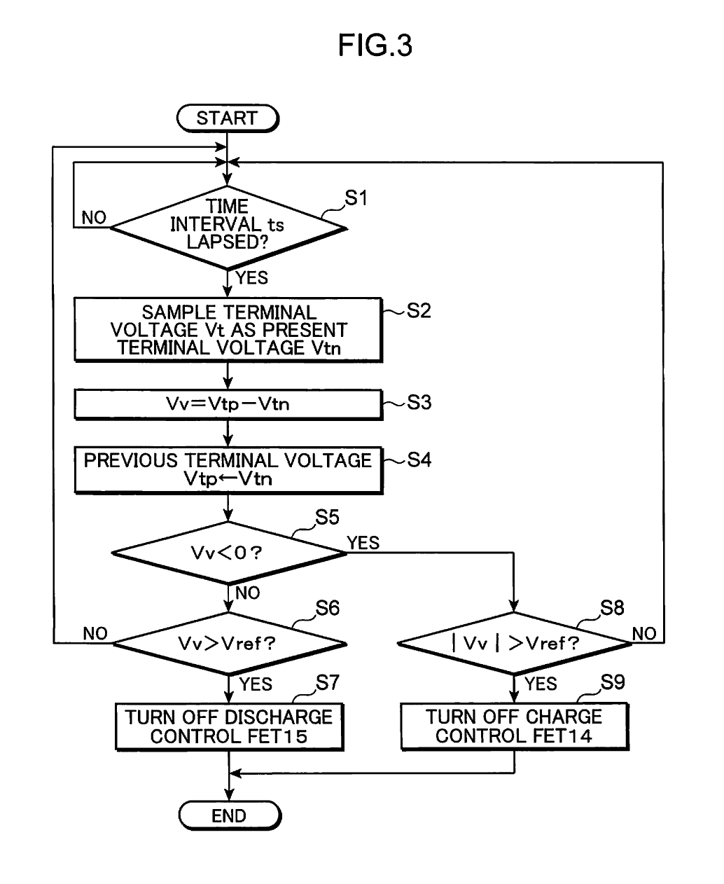

FIG. 3 is a flow chart showing an example of operations of the overcurrent protection circuit 102a shown in FIG. 2. First, normally, the charge control FET 14 and the discharge control FET 15 have been turned on. The sampling unit 111 monitors an elapsed time using the timer circuit (step S1). Each time the time interval ts lapses (YES in step S1), the sampling unit 111 proceeds to step S2 to perform sampling at the time interval ts. A terminal voltage Vt detected by the voltage detecting unit 16 is sampled by the sampling unit 111 as a present terminal voltage Vtn (second voltage) (step S2).

The terminal voltage Vtn is subtracted from a previous terminal voltage Vtp by the difference unit 112 to calculate a variation Vv (step S3). Moreover, when step S3 is initially performed, since the terminal voltage Vtp has not yet been set, step S4 is performed without performing S3 to set the terminal voltage Vtp (first voltage) and a return is made to step S1.

Next, the sampling unit 111 sets the present terminal voltage Vtn as the previous terminal voltage Vtp (first voltage) (step S4).

Next, the overcurrent judging unit 113 verifies whether or not the variation Vv is smaller than zero or, in other words, whether or not the variation Vv has a negative value (step S5). In addition, since the variation Vv not having a negative value (NO in step S5) means that the variation Vv is created by an increase in a current in a discharging direction and a decrease in the terminal voltage Vt, the overcurrent judging unit 113 proceeds to step S6 to verify whether or not an overcurrent has been created due to discharge.

In step S6, the overcurrent judging unit 113 compares the variation Vv with a reference voltage Vref (step S6). If the variation Vv does not exceed the reference voltage Vref (NO in step S6), the overcurrent judging unit 113 judges that an overcurrent due to an abrupt increase in current caused by a short circuit or the like has not occurred and proceeds to step S1 again.

On the other hand, if the variation Vv exceeds the reference voltage Vref (YES in step S6), the overcurrent judging unit 113 judges that an overcurrent due to an abrupt increase in current caused by a short circuit or the like has occurred and proceeds to step S7. Subsequently, the overcurrent judging unit 113 turns off the discharge control FET 15 (step S7) and ends the process. Accordingly, the discharge current of the battery 1 is interrupted and the battery 1 is protected from an overcurrent.

In this case, since the charge control FET 14 is still turned on, even after the discharge current of the battery 1 is interrupted, the battery 1 can be charged with excess power when, for example, the battery pack 100a is used for power conditioning.

On the other hand, in step S5, since the variation Vv having a negative value (YES in step S5) means that the variation Vv is created by an increase in a current in a charging direction and an increase in the terminal voltage Vt, a transfer is made to step S8 to verify whether or not an overcurrent has been created due to charging.

In step S8, the overcurrent judging unit 113 compares an absolute value of the variation Vv with the reference voltage Vref (step S8). If the absolute value of the variation Vv does not exceed the reference voltage Vref (NO in step S8), the overcurrent judging unit 113 judges that an overcurrent due to an abrupt increase in a charge current caused by a failure of a charger or the like has not occurred and proceeds to step S1 again.

On the other hand, if the absolute value of the variation Vv exceeds the reference voltage Vref (YES in step S8), the overcurrent judging unit 113 judges that an overcurrent due to an abrupt increase in a charge current caused by a failure of a charger or the like has occurred and proceeds to step S9. Subsequently, the overcurrent judging unit 113 turns off the charge control FET 14 (step S9) and ends the process. Accordingly, the charge current flowing inside the battery 1 is interrupted and the battery 1 is protected from an overcurrent.

An overcurrent detecting circuit according to an aspect of the present invention includes: a voltage detecting unit that detects a terminal voltage of a battery; a variation detecting unit that detects a variation in the terminal voltage within a base time set in advance, based on a terminal voltage detected by the voltage detecting unit; and an overcurrent judging unit that judges that an overcurrent has flowed inside the battery in a case where a variation detected by the variation detecting unit exceeds a reference threshold value set in advance.

When an overcurrent is created by an abrupt increase in a discharge current of a battery due to a short-circuit fault or by an abrupt increase in a charge current of the battery due to a failure of a charger, a terminal voltage of the battery changes abruptly. Therefore, according to the configuration described above, the variation detecting unit detects a variation in the terminal voltage of the battery within a base time. When an abrupt change in the discharge current or the charge current such as described above occurs, since the variation detected by the variation detecting unit exceeds the reference threshold value, the overcurrent judging unit judges that an overcurrent has flowed inside the battery or, in other words, an overcurrent is detected.

In this case, since an overcurrent is detected based on a variation of the terminal voltage of the battery, an overcurrent of the battery can be detected without using a shunt resistor or an on-resistance of an FET.

In addition, favorably, the variation detecting unit includes: a delaying unit that creates a delayed voltage that is a voltage obtained by delaying a change in a terminal voltage of the battery by the base time; and a difference unit that detects, as the variation, a difference between a delayed voltage created by the delaying unit and a terminal voltage detected by the voltage detecting unit.

According to the configuration described above, the delaying unit creates a delayed voltage in which a change in the terminal voltage of the battery has been delayed. In addition, the difference unit detects a difference between the delayed voltage and the terminal voltage as a variation. In this case, when the terminal voltage of the battery changes, the more abrupt the change or, in other words, the greater the variation of the terminal voltage within the base time, the greater the difference between the terminal voltage and the delayed voltage. Therefore, a variation detected by the difference unit represents a variation of the terminal voltage within the base time. Consequently, the variation detecting unit can be simply configured using the delaying unit and the difference unit.

Furthermore, favorably, the delaying unit is a first-order lag circuit using a resistor and a capacitor.

According to the configuration described above, since the delaying unit can be configured using a resistor and a capacitor, the delaying unit can be simplified.

Moreover, the variation detecting unit may include: a sampling unit that samples a terminal voltage detected by the voltage detecting unit as a first voltage, and samples, as a second voltage, a terminal voltage detected by the voltage detecting unit upon a lapse of a time interval set in advance from the sampling of the first voltage; and a difference unit that detects, as the variation, a difference between the first voltage and the second voltage.

According to the configuration described above, since the difference unit directly detects a variation in a terminal voltage of the battery within a period of a time interval set in advance, a detection accuracy of the variation is improved.

In addition, favorably, a switching unit that interrupts a current flowing inside the battery is further provided, wherein in a case where a variation detected by the variation detecting unit exceeds the reference threshold value, the overcurrent judging unit causes the switching unit to interrupt a current flowing inside the battery.

According to the configuration described above, when a variation detected by the variation detecting unit exceeds the reference threshold value, the overcurrent judging unit judges that an overcurrent has flowed inside the battery and the switching unit interrupts a current flowing inside the battery. Accordingly, a risk of degradation of the battery due to an overcurrent is reduced.

Moreover, favorably, the switching unit includes: a charging switching element that interrupts only a current in a direction charging the battery; and a discharging switching element that is connected in series to the charging switching element and interrupts only a current in a direction the battery discharges, and the overcurrent judging unit interrupts the current by turning off the discharging switching element in a case where a variation detected by the variation detecting unit is a variation in a direction in which the terminal voltage decreases and the variation exceeds the reference threshold value, and interrupts the current by turning off the charging switching element in a case where a variation detected by the variation detecting unit is a variation in a direction in which the terminal voltage increases and the variation exceeds the reference threshold value.

A terminal voltage of a battery decreases when a current in a discharging direction flows and increases when a current in a charging direction flows. Consequently, when a variation detected by the variation detecting unit is a variation in a direction in which the terminal voltage decreases and when the variation exceeds the reference threshold value, it is conceivable that an overcurrent has occurred due to an increase in discharge current. At this point, the overcurrent judging unit interrupts a current flowing inside the battery by turning off the discharging switching element. In this case, since the charging switching element has not been turned off, the battery can be protected from an overcurrent in the discharging direction while maintaining the battery in a chargeable state.

On the other hand, when a variation detected by the variation detecting unit is a variation in a direction in which the terminal voltage increases and when the variation exceeds the reference threshold value, it is conceivable that an overcurrent has occurred due to an increase in charge current. At this point, the overcurrent judging unit interrupts a current flowing inside the battery by turning off the charging switching element. In this case, since the discharging switching element has not been turned off, the battery can be protected from an overcurrent in the charging direction while maintaining the battery in a dischargeable state.

In addition, favorably, a first diode that is connected in parallel to the charging switching element and a second diode that is connected in parallel to the discharging switching element are further provided, wherein the first diode is arranged in a direction that is a forward direction relative to a current in a direction discharging the battery, and the second diode is arranged in a direction that is a forward direction relative to a current in a direction charging the battery.

According to the configuration described above, since a discharge current of the battery flows so as to bypass the charging switching element via the first diode, the charging switching element is able to interrupt only a charge current of the battery. Since a charge current of the battery flows so as to bypass the discharging switching element via the second diode, the discharging switching element is able to interrupt only a discharge current of the battery.

Furthermore, a battery pack according to an aspect of the present invention includes the above-described overcurrent detecting circuit and the battery.

According to the configuration described above, in the battery pack, since an overcurrent is detected based on a variation of a terminal voltage of the battery, an overcurrent of the battery can be detected without using a shunt resistor or an on-resistance of an FET.

With an overcurrent detecting circuit and a battery pack configured as described above, since an overcurrent is detected based on a variation of a terminal voltage of the battery, an overcurrent of the battery can be detected without using a shunt resistor or an on-resistance of an FET.

The present application is based on and claims the benefit of Japanese Patent Application No. 2010-119129, filed May 25, 2010, the content of which is hereby incorporated by reference in its entirety.

The specific embodiments and examples in the section titled Description of Embodiments have been described for the sole purpose of illustrating the technical contents of the present invention and the present invention should not be interpreted narrowly only to such specific examples. Rather, various modifications may be made without departing from the spirit of the invention and from the scope of the following claims.

### INDUSTRIAL APPLICABILITY

An overcurrent detecting circuit and a battery pack according to the present invention can be suitably used in battery-mounted apparatuses and systems including electronic devices such as a mobile personal computer, a digital camera, a video camera and a mobile phone, vehicles such as an electric car and a hybrid car, power systems combining a photovoltaic cell or a power-generating device with a secondary battery, and an uninterruptible power source equipment.

1. An overcurrent detecting circuit comprising:
a voltage detecting unit that detects a terminal voltage of a battery;
a variation detecting unit that detects a variation in the terminal voltage within a base time set in advance, based on a terminal voltage detected by the voltage detecting unit; and
an overcurrent judging unit that judges that an overcurrent has flowed inside the battery in a case where a variation detected by the variation detecting unit exceeds a reference threshold value set in advance.

2. The overcurrent detecting circuit according to claim 1, wherein
the variation detecting unit includes:
a delaying unit that creates a delayed voltage that is a voltage obtained by delaying a change in a terminal voltage of the battery by the base time; and
a difference unit that detects, as the variation, a difference between a delayed voltage created by the delaying unit and a terminal voltage detected by the voltage detecting unit.

3. The overcurrent detecting circuit according to claim 2, wherein
the delaying unit is a first-order lag circuit using a resistor and a capacitor.

4. The overcurrent detecting circuit according to claim 1, wherein
the variation detecting unit includes:
a sampling unit that samples a terminal voltage detected by the voltage detecting unit as a first voltage, and samples, as a second voltage, a terminal voltage detected by the voltage detecting unit upon a lapse of a time interval set in advance from the sampling of the first voltage; and
a difference unit that detects, as the variation, a difference between the first voltage and the second voltage.

5. The overcurrent detecting circuit according to claim 1, further comprising a switching unit that interrupts a current flowing inside the battery, wherein
in a case where a variation detected by the variation detecting unit exceeds the reference threshold value, the overcurrent judging unit causes the switching unit to interrupt a current flowing inside the battery.

6. The overcurrent detecting circuit according to claim 5, wherein
the switching unit includes:
a charging switching element that interrupts only a current in a direction charging the battery; and
a discharging switching element that is connected in series to the charging switching element and interrupts only a current in a direction the battery discharges, and
the overcurrent judging unit interrupts the current by turning off the discharging switching element in a case where a variation detected by the variation detecting unit is a variation in a direction in which the terminal voltage decreases and the variation exceeds the reference threshold value, and
interrupts the current by turning off the charging switching element in a case where a variation detected by the variation detecting unit is a variation in a direction in which the terminal voltage increases and the variation exceeds the reference threshold value.

7. The overcurrent detecting circuit according to claim 6, further comprising:
a first diode that is connected in parallel to the charging switching element; and
a second diode that is connected in parallel to the discharging switching element, wherein
the first diode is arranged in a direction that is a forward direction relative to a current in a direction discharging the battery, and
the second diode is arranged in a direction that is a forward direction relative to a current in a direction charging the battery.

8. A battery pack comprising:
the overcurrent detecting circuit according to claim 1; and
the battery.
